(19) United States
(12) Patent Application Publication
(10) Pub. No.: US 2013/0240484 A1
(43) Pub. Date: Sep. 19, 2013

(54) ELECTROLESS COPPER ALLOY CAPPING

(71) Applicant: Artur KOLICS, Dublin, CA (US)

(72) Inventor: Artur KOLICS, Dublin, CA (US)

(73) Assignee: LAM RESEARCH CORPORATION, Fremont, CA (US)

(21) Appl. No.: 13/424,141

(22) Filed: Mar. 19, 2012

(51) Int. Cl. B05D 5/00; C23C 16/06; B05D 3/10; C23C 16/56; B05D 1/38; B05D 3/02

(52) U.S. Cl. 216/105; 427/265; 427/250

(57) ABSTRACT

A method for providing copper filled features in a layer is provided. A deposition of copper is provided to fill features in the layer. Tops of the copper deposit are cleaned to remove copper or copper oxide at tops of the copper deposit. A selective copper alloy plating on the tops of the copper deposit is provided. The copper deposit and selective copper alloy plating are annealed.

### BACKGROUND OF THE INVENTION

1. Field of the Invention

The invention relates to a method of forming semiconductor devices on a semiconductor wafer. More specifically, the invention relates to forming metal interconnects in low-k dielectric layers.

In forming semiconductor devices, conductive metal interconnects are placed in low-k dielectric layers. This may be done by depositing copper or a copper alloy into features etched into the low-k dielectric layer. The deposited copper may be deposited by electrodeposition or by electroless deposition. Electromigration of copper increases the failure rate of such interconnects. As feature size decreases, electromigration becomes a more significant problem.

### SUMMARY OF THE INVENTION

To achieve the foregoing and in accordance with the purpose of the present invention, a method for providing copper filled features in a layer is provided. A deposition of copper is provided to fill features in the layer. Tops of the copper deposit are cleaned to remove copper or copper oxide at tops of the copper deposit. A selective copper alloy plating on top of the copper deposit is provided. The copper deposit and selective copper alloy plating are annealed.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIGS. 2A-F are schematic views of the formation of structures using the inventive process.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Copper contacts are prone to electromigration. Electromigration may cause the circuits made from the copper contacts to fail. With the reduction of size of the copper contacts, failure due to electromigration increases. A preferred embodiment of the invention reduces failure caused by electromigration.

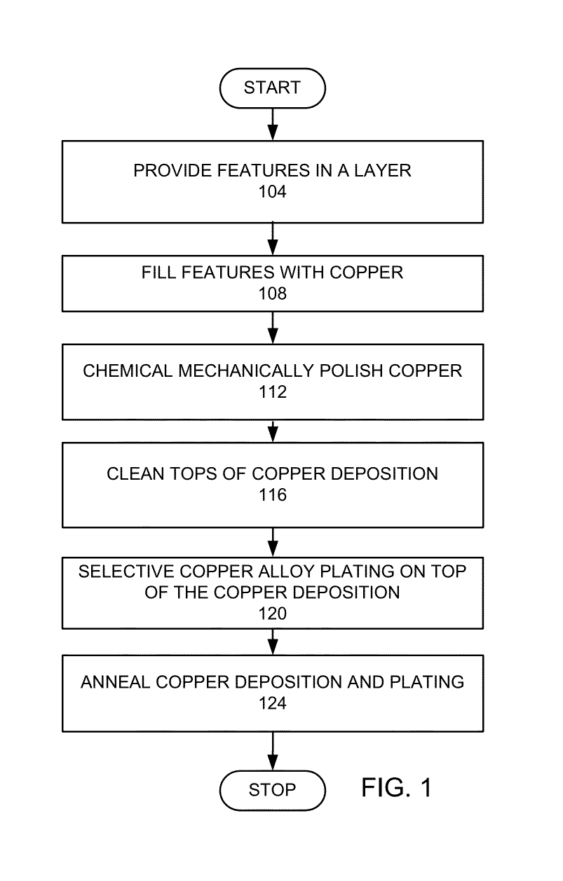

FIG. 1 is a high level flow chart of an embodiment of the invention. In this embodiment, features are provided in a layer (step 104). The features are filled with copper (step 108). Chemical mechanical polishing (CMP) is used to polish the copper back to the tops of the features (step 112). The tops of the copper deposit in the features are cleaned (step 116). This causes tops of the copper deposit to be below the tops of the features and removes any copper oxide on tops of the copper deposit. A selective copper alloy plating is provided on the tops of the copper deposit (step 120). The copper deposit and copper alloy plating are annealed (step 124).

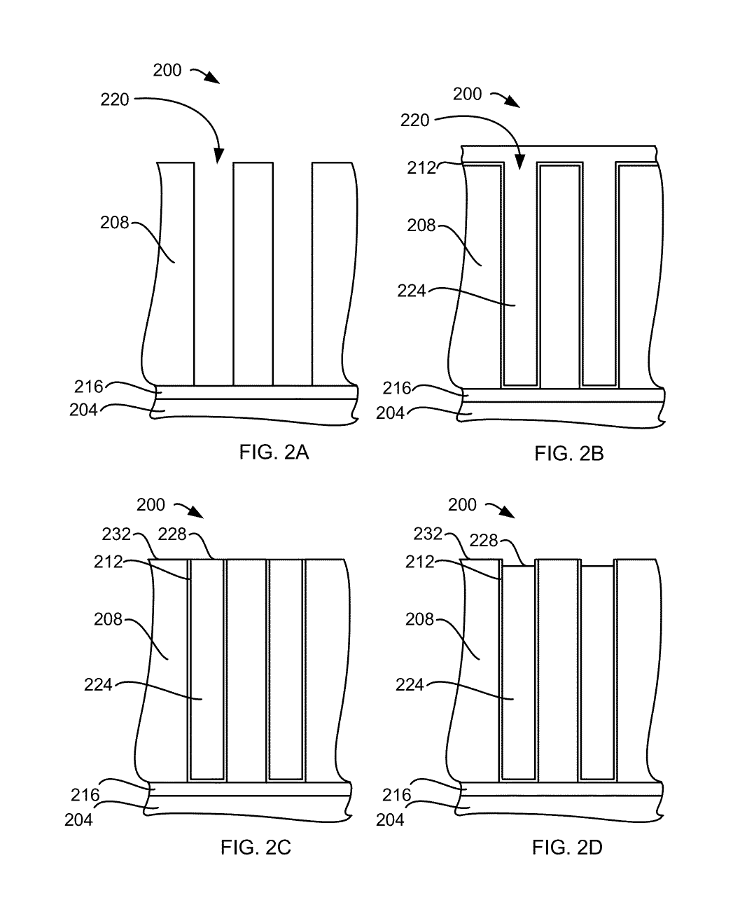

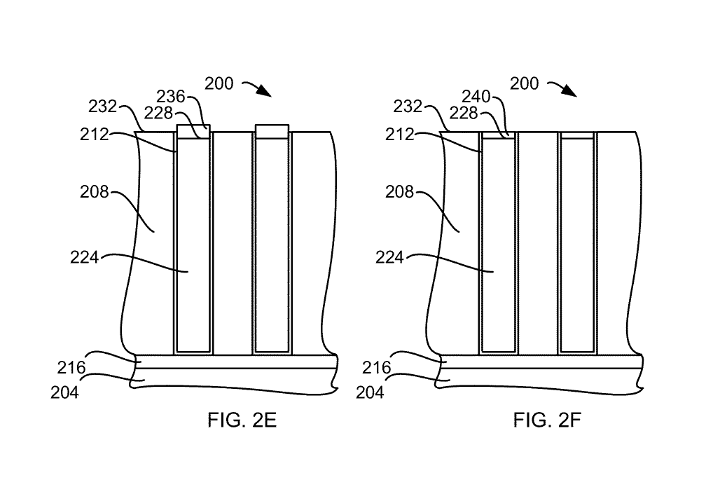

In a preferred embodiment of the invention, features are provided in a layer (step 104). FIG. 2A is a schematic cross-sectional view of a stack 200 with a substrate 204 with a layer 208 with features 220. In this example, one or more layers 216 are disposed between the substrate 204 and the layer 208. In this example the layer 208 with features 220 is a dielectric layer. More preferably, the layer 208 is a low-k dielectric layer, with a k value of less than 4.0. In this embodiment, the layer is organosilicate glass (OSG). The features may be formed by etching the layer 208.

The features are filled with a copper deposit (step 108). The copper deposit may be pure copper or a copper alloy. FIG. 2B is a schematic cross-sectional view of the stack 200 with a substrate 204 with a layer 208 with features 220, which are filled with a copper deposit 224. The copper deposit is preferably provided using electroplating. In other embodiments, electroless copper deposition may be used. In other embodiments, other copper deposition processes may be used. In this embodiment, a barrier layer 212 is formed over the layer 208 before the copper deposition. Other steps may be provided in other embodiments to form or shape other layers.

Chemical mechanical polishing is used to polish the copper back to the tops of the features, removing excess deposited copper outside of the features (step 112). FIG. 2C is a schematic cross-sectional view of the stack 200 after the excess copper outside of the features has been removed. In this embodiment, the tops 228 of the copper deposit 224 are even with the tops 232 of the layer 208 of the stack 200. In other embodiments, the tops 228 of the copper deposit 224 are not even with the tops 232 of the layer 208 of the stack 200. In other embodiments other methods may be used to remove excess copper over the stack 200 and expose tops of the copper deposit.

The tops of the copper deposit are cleaned to remove copper or copper oxide from the tops of the copper deposit (step 116). In this embodiment, an acid bath is used to provide the copper deposit clean, which removes both copper oxide and copper. In this embodiment, the acid bath may be an organic acid such as citric acid or oxalic acid. FIG. 2D is a schematic cross-sectional view of the stack 200 after the copper deposit is cleaned. In this embodiment the tops 228 of the copper deposit 224 are below the tops 232 of the layer 208 of the stack 200. The acid bath may also remove excess copper on tops 232 of the layer 208.

A selective copper alloy plating provides a deposition on top of the copper deposit 224 (step 120). The copper alloy plating is selectively deposited on the tops 228 of the copper deposit 224 with respect to the tops 232 of the layer 208. Such a selective deposition may be provided using electroless plating, chemical vapor deposition (CVD), or atomic layer deposition (ALD). Some of the copper alloys may be copper with an alloy component of at least one of tin, cobalt, nickel, indium, ruthenium, rhenium, tungsten, molybdenum, palladium, gallium, germanium, zinc, or manganese. Preferably, the alloy component is at least 1% of the copper alloy. More preferably, the alloy component is at least 5-20% of the copper alloy. Preferably, the copper alloy is 80-99% copper. More preferably, the copper alloy is 80-95% copper. An example of an electroless copper bath provides 1-2 g/L of copper sulfate, 0.2-0.6 g/L of nickel sulfate, 15-20 g/L of sodium citrate, 8-12 g/L of sodium hypophosphite, and 5-10 g/L of boric acid. NaOH is used to adjust the pH of the bath to pH 9-9.5. The temperature of the bath is maintained between 50° C. to 80° C. FIG. 2E is a schematic cross-sectional view of the stack 200 after the copper alloy plating 236 has been selectively deposited on the tops 228 of the copper deposit 224. In this embodiment, the tops of the copper alloy plating 236 extend above the tops 232 of the layer 208. In a preferred embodiment, the tops of the copper alloy plating 236 are even with the tops 232 of the layer 208.

The copper deposit and copper alloy plating are annealed (step 124). FIG. 2F is a schematic cross-sectional view of the stack 200 after the copper deposit 224 and copper alloy plating are annealed. In this embodiment, the copper alloy plating forms an annealed copper alloy cap 240 on top of the copper deposit 224, which reduces electromigration. In other embodiments the alloys pass into the copper deposit 224 to provide improved copper deposit properties, such as reducing electromigration. In this embodiment, the annealing is performed at a temperature in the range of 200 to 450° C. for a time between 1 to 60 minutes. More preferably, the anneal is at a temperature of 250 to 400° C. for a time between 5 to 30 minutes.

In one embodiment, the copper alloy is an alloy of copper with manganese. During the annealing, it is believe that the manganese would migrate to the copper and dielectric interface to provide a better seal to the barrier layer, while leaving a lower resistance copper alloy layer with little manganese to cap the copper deposit. It should be noted that the small amount of manganese remaining in the copper alloy cap will increase the resistance of the copper alloy cap.

In another embodiment, the copper alloy plating is an alloy of copper with rhenium. In this embodiment, during annealing the copper and rhenium separate, so that the copper mixes with the copper deposit and the rhenium forms a rhenium cap on top of the copper deposit. The rhenium cap reduces electromigration and only slightly increases resistance. In one embodiment, the formation of subsequent electrical contacts to the copper deposit opens the rhenium cap, so that the rhenium cap does not provide any increase in resistance.

In another embodiment of the invention, the copper alloy plating is an alloy of copper and indium. During the annealing, the indium and copper separate, where the indium moves to interfaces. The indium seals the boundaries of the copper, such as next to the barrier layer and the top of the copper deposit. In addition, the indium moves to the grain boundaries of the copper deposit. The indium will improve the barrier layer and in addition at the grain boundaries and cap reduce electromigration of the copper. The reduction of electromigration at the grain boundaries has been found to be more important for thinner contacts.

In another embodiment, the copper alloy plating is an alloy of copper, tin, and manganese. During the annealing, the tin and manganese separate out from the copper. The tin goes to the grain boundaries and the manganese goes to the interfaces and forms a cap, so that the tin reduces electromigration at the grain boundaries and the manganese reduces electromigration at the interfaces and the top of the copper deposit and improves the interfaces, such as at the barrier layer.

In another embodiment, the copper alloy plating is an alloy of copper, tin, and cobalt. During the annealing, the tin and cobalt separate out from the copper. The tin goes to the grain boundaries and the cobalt forms a cap, so that the tin reduces electromigration at the grain boundaries and the cobalt reduces electromigration at the top of the copper deposit.

In another embodiment, the copper alloy plating is an alloy of copper, tin, phosphor and cobalt. During the annealing, the tin, phosphorous, and cobalt separate out from the copper. The tin goes to the grain boundaries and the cobalt and phosphorous form a cap, so that the tin reduces electromigration at the grain boundaries and the cobalt reduces electromigration at the top of the copper deposit. Another embodiment may also add tungsten to the alloy.

Other embodiments use a copper and cobalt alloy with the addition of indium, germanium, gallium, zinc, palladium,

The transfer time from the CMP tool to the next processing tool may provide sufficient wait time of up to 24 hours to form a copper oxide layer on tops of the copper deposit. The cleaning of the tops of the copper deposit removes copper oxide, which reduces line resistance. However, the removal of the copper oxide also results in the removal of some copper, which may increase line resistance by 3%-5%, if the copper is replaced by another metal, such as cobalt. The selective copper alloy plating replaces the removed copper with a copper alloy that either remains as a copper alloy during annealing or separates to a copper layer where the alloy material may quickly pass through the remaining copper deposit during the annealing. If the alloy component separates from the copper and forms a cap during annealing, the alloy component cap may be ultra thin to provide a lower resistance. For example if the selective copper alloy plating provides a cap layer that is 20 Å thick that has about 20% alloy component, when the alloy component separates out and forms a cap during the anneal, the alloy makes a cap 20% the thickness of the plating cap layer. Therefore, the alloy cap would be 4 Å thick, when separated out during annealing.

In addition, the use of electroless deposition for the selective copper alloy plating eliminates overhang, which reduces problems with scaling to small feature sizes. In addition, the electroless deposition provides a high selectivity to reduce or eliminate deposition on the tops of the layer while depositing on top of the copper deposit. The use of electroless deposition also allows for a short time between the acid bath for cleaning and the bath for electroless deposition, since these processes may be done in the same chamber. Such a short time reduces the formation of copper oxide after cleaning. Depending on the alloy component, the cap may reduce the formation of copper oxide.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for providing copper filled features in a layer, comprising:
providing a deposition of copper to fill features in the layer;
cleaning tops of the copper deposit to remove copper or copper oxide at the tops of the copper deposit;
providing a selective copper alloy plating on the tops of the copper deposit; and
annealing the copper deposit and selective copper alloy plating.

2. The method, as recited in claim 1, further comprising removing excess copper over the layer to expose the tops of the copper deposit, before cleaning the tops of the copper deposit.

3. The method, as recited in claim 2, wherein the cleaning the tops of the copper deposit results in the tops of the copper deposit to be lower than tops of the layer.

4. The method, as recited in claim 3, wherein the cleaning tops of the copper deposit comprises exposing the tops of the copper deposit to an acid bath.

5. The method, as recited in claim 4, wherein the removing excess copper over the layer, comprises providing a chemical mechanical polishing of the deposition of copper before cleaning the tops of the copper deposit.

6. The method, as recited in claim 5, wherein the providing the selective copper alloy plating selectively deposits the copper alloy plating on the tops of the copper deposit.

7. The method, as recited in claim 6, wherein the providing the selective copper alloy plating comprises one of electroless deposition, chemical vapor deposition, or atomic layer deposition.

8. The method, as recited in claim 7, wherein the providing the selective copper alloy plating comprises electroless deposition, comprising exposing the tops of the copper deposit to an electroless copper alloy deposition bath.

9. The method, as recited in claim 8, wherein the copper alloy plating comprises copper and at least one additive of tin, cobalt, nickel, indium, ruthenium, rhenium, tungsten, molybdenum, palladium, gallium, germanium, zinc, or manganese.

10. The method, as recited in claim 9, wherein the annealing the copper deposit and copper alloy forms a copper alloy cap layer over the copper deposit.

11. The method, as recited in claim 9, wherein the annealing the copper deposit and copper alloy causes the copper alloy to separate to copper and at least one additive.

12. The method, as recited in claim 11, wherein the at least one additive forms a cap layer.

13. The method, as recited in claim 11, wherein the at least one additive diffuses through the copper to a copper barrier interface.

14. The method, as recited in claim 11, wherein the at least one additive diffuses through the copper to copper grain boundaries.

15. The method, as recited in claim 1, wherein the cleaning the tops of the copper deposit comprises exposing the tops of the copper deposit to an acid bath.

16. The method, as recited in claim 1, wherein the providing the selective copper alloy plating comprises one of electroless deposition, chemical vapor deposition, or atomic layer deposition.

17. The method, as recited in claim 1, wherein the providing the selective copper alloy plating comprises electroless deposition, comprising exposing tops of the copper deposit to an electroless copper alloy deposition bath.

18. The method, as recited in claim 1, wherein the copper alloy plating comprises copper and at least one additive of tin, cobalt, nickel, indium, ruthenium, rhenium, tungsten, molybdenum, palladium, gallium, germanium, zinc, or manganese.

19. The method, as recited in claim 1, wherein the annealing the copper deposit and copper alloy causes the copper alloy to separate to copper and at least one additive.

20. The method, as recited in claim 19, wherein the at least one additive diffuses through the copper to copper grain boundaries.
